(19) United States
(12) Patent Application Publication
(10) Pub. No.: US 2025/0264423 A1
(43) Pub. Date: Aug. 21, 2025

(54) CHARGED PARTICLE DETECTOR FOR MICROSCOPY

(71) Applicant: ASML Netherlands B.V., Veldhoven (NL)

(72) Inventor: Ilse VAN WEPEREN, Veldhoven (NL)

(73) Assignee: ASML Netherlands B.V., Veldhoven (NL)

(21) Appl. No.: 19/176,068

(22) Filed: Apr. 10, 2025

Related U.S. Application Data
(63) Continuation of application No. PCT/EP2023/075534, filed on Sep. 15, 2023.

(30) Foreign Application Priority Data
Oct. 11, 2022 (EP) 22200760.1

(51) Int. Cl. G01N 23/2251; G01N 23/203

(52) U.S. Cl. CPC G01N 23/2251; G01N 23/203; G01N 2223/303; G01N 2223/501

(57) ABSTRACT

A method of configuring a detector of a charged particle assessment system, the detector having an array of sensing elements configured to generate electrical signals in response to incident secondary particles or backscattered particles from a sample, the method comprising:

selecting a first subset of the set of sensing elements for activation based on data derived from a predicted distribution of secondary particles or backscattered particles; and selecting a second subset of the set of sensing elements for deactivation based on the predicted distribution;

wherein the first subset has a different predicted ratio of incident secondary particles to incident backscattered particles than the second subset.

### CROSS-REFERENCE TO RELATED APPLICATIONS

This application claims priority of International application PCT/EP2023/075534, filed on Sep. 15, 2023, which claims priority of EP Application Serial No. 22200760.1, filed on Oct. 11, 2022. These applications are incorporated herein by reference in their entireties.

### FIELD

The description herein relates to charged particle detection, and more particularly, to systems and methods that may be applicable to charged particle beam detection.

### BACKGROUND

Detectors may be used for sensing physically observable phenomena. For example, charged particle beam tools, such as electron microscopes, may comprise detectors that receive charged particles projected from a sample and that output a detection signal. Detection signals can be used to reconstruct images of sample structures under inspection and may be used, for example, to reveal defects in the sample. Detection of defects in a sample is increasingly important in the manufacturing of semiconductor devices, which may include large numbers of densely packed, miniaturized integrated circuit (IC) components. Dedicated inspection tools may be provided for this purpose.

In some applications in the field of inspection, for example microscopy using a scanning electron microscope (SEM), an electron beam may be scanned across a sample to derive information from backscattered or secondary electrons generated from the sample. Backscattered electrons (or more generally backscattered particles) and secondary electrons (or more generally secondary particles) may be referred to collectively as returning particles. In a related art, electron detection systems in SEM tools may include a detector configured to detect electrons coming from the sample. Existing detectors in SEM tools may detect only the intensity of the beam. Sensitivity in conventional detection systems may be limited by poor signal-to-noise ratio (SNR), particularly when beam current reduces to, for example, pico-ampere ranges. In some detection methods, a large area semiconductor detector or a group of small area semiconductor detectors having an area equal to, smaller, or larger than the area of the beam spot may be used. Current induced by the incoming electron beam may be generated within the detector and then amplified by an amplifier following the detector.

With continuing miniaturization of semiconductor devices, inspection systems may use lower and lower electron beam currents. As beam current decreases, maintaining SNR becomes even more difficult. For example, when probe current decreases to 200 pA or below, SNR may drop off dramatically. Poor SNR may require taking measures such as image averaging or extending the integration time of signals corresponding to each pixel in the image of the sample, which may increase the electron dose on the sample surface, resulting in surface charging artifacts or other detrimental effects. Such measures may also lower the overall throughput of the inspection system.

In a related art, particle counting may be useful in low-current applications. Particle counting may be employed in detectors such as an Everhart-Thornley detector (ETD), which may use a scintillator and a photomultiplier tube (PMT). An ETD may exhibit good SNR in probe current ranges of some applications, such as 8 pA to 100 pA. However, the scintillator's light yield may degrade with accumulated electron dose and thus has a limited lifetime. Aging of the scintillator may also cause performance drift at the system level and may contribute to generating non-uniform images. Therefore, an ETD may not be appropriate for use in an inspection tool, especially when used in semiconductor manufacturing facilities where it may be required to run 24 hours per day, 7 days per week.

A charged particle detector is needed that can achieve high SNR and good performance with a wide range of probe currents, for example from about 40 pA to InA. Meanwhile, a detector should secure stable quantum efficiency and long lifetime with low performance drift, for example even when used with probe currents of 1 nA or more in continuous operation.

Detection systems employing related art methods may face limitations in detection sensitivity and SNR, particularly at low electron dosages. To improve SNR, related art has proposed a so-called pixelated electron-counting detector in which a detector is sub-divided into a large number of sensing elements whose outputs are combined to generate a detection signal. However, pixelated electron-counting detectors do still suffer from noise and further improvements in this regard are desired.

### SUMMARY

Embodiments of the present disclosure provide a method of calibrating a charged particle detector in a charged particle assessment apparatus, the charged particle detector having an array of sensing elements that are configured to generate electrical signals in response to incident secondary particles or backscattered particles from the sample; the method comprising:
scanning a charged particle beam across a calibration sample including a feature of interest (e.g. an edge) and a flat topography;
receiving electrical signals from the sensing elements in response to returning particles generated in response to the charged particle beam to obtain a feature distribution of returning particles as a function of position on the detector for the feature topography and a flat distribution of returning particles as a function of position on the detector for the flat topography; and
selecting a subset of the sensing elements to be used for assessment of a sample based on the feature distribution and the flat distribution.

Embodiments of the present disclosure provide a method of calibrating a charged particle detector in a charged particle assessment apparatus, the charged particle detector having an array of sensing elements that are configured to generate electrical signals in response to incident secondary particles or backscattered particles from the sample; the method comprising:
scanning a charged particle beam across a calibration sample having a known topography;
receiving electrical signals from the sensing elements in response to secondary particles and backscattered particles generated in response to the charged particle beam to obtain a combined distribution of secondary particles and backscattered particles as a function of position on the detector;
estimating a distribution of backscattered particles amongst the secondary particles and backscattered particles as a function of position on the detector;
subtracting the distribution of backscattered particles from the combined distribution of secondary particles and backscattered particles to obtain a distribution of secondary particles; and
selecting a subset of the sensing elements to be used for assessment of a sample based on the distribution of backscattered particles and the distribution of secondary particles.

Embodiments of the present disclosure provide a charged particle assessment system comprising:
a charged-particle beam apparatus configured to direct a charged particle beam onto a sample so that secondary particles and backscattered particles are generated in response to the charged particle beam;
an array of sensing elements configured to generate electrical signals in response to incident secondary particles or backscattered particles from the sample; and
a controller configured to selectively activate a first subset of the set of sensing elements, to selectively deactivate a second subset of the set of sensing elements and to combine the electrical signals of the selected subset into a detector output signal, wherein the selective activation and selective deactivation are based on a predicted distribution of secondary particles or backscattered particles.

Embodiments of the present disclosure provide a method of detecting charged particles comprising:
configuring a detector of a charged particle assessment system by the method described above;
directing a charged particle beam onto a sample using the charged particle assessment system so that secondary particles and backscattered particles are generated in response to the charged particle beam;
directing the secondary particles and backscattered particles to the detector;
activating the first subset of the array of sensing elements;
combining the electrical signals of the first subset into a detector output signal; and
deactivating the second subset of the array of sensing elements.

Embodiments of the present disclosure provide a method of configuring a detector of a charged particle assessment system, the detector having an array of sensing elements configured to generate electrical signals in response to incident secondary particles or backscattered particles from a sample, the method comprising:
selecting a first subset of the set of sensing elements for activation based on data derived from a predicted distribution of secondary particles or backscattered particles; and
selecting a second subset of the set of sensing elements for deactivation based on the predicted distribution;
wherein the first subset has a different predicted ratio of incident secondary particles to incident backscattered particles than the second subset.

It is to be understood that both the foregoing general description and the following detailed description are exemplary and explanatory only and are not restrictive of the disclosed embodiments, as may be claimed.

### BRIEF DESCRIPTION OF THE DRAWINGS

The above and other aspects of the present disclosure will become more apparent from the description of exemplary embodiments, taken in conjunction with the accompanying drawings in which:

FIG. 1 is a schematic diagram illustrating an exemplary electron beam inspection (EBI) system, consistent with embodiments of the present disclosure.

FIG. 2A, FIG. 2B, and FIG. 2C are schematic diagrams illustrating exemplary electron beam tools, consistent with embodiments of the present disclosure that may be a part of the exemplary electron beam inspection system of FIG. 1.

FIG. 3 is a schematic diagram of a radiation detector, consistent with embodiments of the present disclosure.

FIGS. 4A, B and C are diagrams of the location of incidence on a detector of electrons of different origins, obtained from simulations.

FIG. 5 is a diagram indicating active and non-active parts of the radiation detector of FIG. 3 in a first mode.

FIGS. 6A and 6B are diagrams indicating active and non-active parts of the radiation detector of FIG. 3 in a second mode.

FIGS. 7A and 7B are histograms of the probability of incidence of electrons on the detector of FIG. 3 at different radii when the scanning beam is incident on flat topography and on a topography including an edge.

FIG. 8 is a diagram explaining a contrast to noise ratio metric.

FIG. 9 is a sketch illustrating secondary electron yield in the vicinity of an edge on a sample under assessment.

FIG. 10 is a diagram illustrating selection of inner and outer radii of an active region to maximize sensitivity to edges.

### DETAILED DESCRIPTION

Reference will now be made in detail to exemplary embodiments, examples of which are illustrated in the drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses, systems, and methods consistent with aspects related to subject matter that may be recited in the appended claims.

Aspects of the present application relate to systems and methods for charged particle beam detection. Systems and methods may employ counting of charged particles, such as electrons, and may be useful in an inspection tool, such as a scanning electron microscope (SEM). Inspection tools may also be referred to as assessment tools or assessment apparatuses. Inspection tools may be used in the manufacturing process of integrated circuit (IC) components. To realize the enhanced computing power of modern-day electronic devices, the physical size of the devices may shrink while the packing density of circuit components, such as, transistors, capacitors, diodes, etc., is significantly increased on an IC chip. For example, in a smartphone, an IC chip (which may be the size of a thumbnail) may include over 2 billion transistors, the size of each transistor being less than 1/1,000th of a human hair. Not surprisingly, semiconductor IC manufacturing is a complex process, with hundreds of individual steps. Errors in even one step have the potential to dramatically affect the functioning of the final product. The goal of the manufacturing process is to improve the overall yield of the process. For example, for a 50-step process to get 75% yield, each individual step must have a yield greater than 99.4%, and if the individual step yield is 95%, the overall process yield drops to 7%.

It is increasingly important to ensure the ability to detect defects with high accuracy and high resolution while maintaining high throughput (defined as the number of wafer processed per hour, for example). High process yields and high wafer throughput may be impacted by the presence of defects, especially when operator intervention is involved. Thus, detection and identification of micro and nano-sized defects by inspection tools (such as a SEM) is important for maintaining high yields and low cost.

In some inspection tools, a sample may be inspected by scanning a beam of high energy electrons over the sample surface. Due to interactions at the sample surface, secondary or backscattered electrons may be generated from the sample that may then be detected by a detector.

A backscattered electron is when an electron from the beam which is scanned across the sample is scattered by an atom in the sample back in the direction of the detector. A secondary electron is when an atom of the sample is caused by the beam to emit an electron. In many cases, the rate of backscattered electrons is quite random whereas the rate of secondary electrons varies according to the properties of the surface of the sample. In such cases, the backscattered electrons may be considered noise, whereas the secondary electrons are the signal that it is desired to detect. Because all electrons are intrinsically the same, it is very difficult to distinguish between backscattered and secondary electrons. Backscattered electrons may have higher energy than secondary electrons and there have been proposals to distinguish between secondary electrons and backscattered electrons on this basis but practical implementations of this idea are difficult.

The present inventor has determined that the backscattered electrons are often emitted from the sample in different directions than the secondary electrons. The distributions of the backscattered electrons and of the secondary electrons overlap but the distribution of the backscattered electrons is wider than the distribution of the secondary electrons. Therefore by using pixelated detector (i.e. a detector that has many separate pixels that emit separate signals when they detect electrons) it is possible to select the output from some pixels and reject the output from other pixels in order to control the ratio of detected backscattered electrons to detected secondary electrons. Several desirable effects can thereby be achieved: for example the signal to noise ratio can be improved; the contrast to noise ratio can be improved; or the sensitivity to specific feature types on the sample can be improved.

In some embodiments of the present disclosure, a sensing element of an array may be sized such that no more than a certain number of charged particles is received in the area of the individual sensing element per sampling period. The certain number may be one. The size of the sensing element may be smaller than a geometric spread of charged particles incident on the detector. Thus, an individual sensing element may be configured to receive fewer charged particles than the total number of charged particles incident on the detector. According to various criteria, aspects of the detector may be set so as to enable charged particle counting, such as a size of sensing elements, sampling rate, and other characteristics.

Without limiting the scope of the present disclosure, some embodiments may be described in the context of providing detectors and detection methods in systems utilizing electron beams. However, the disclosure is not so limited. Other types of charged particle beams may be similarly applied. Furthermore, systems and methods for detection may be used in other imaging systems, such as optical imaging, photon detection, x-ray detection, ion detection, etc.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C.

Additionally, the term “detector element” may include or cover “sensing element,” “sensor element,” “detection cell,” or “detector segment,” etc., A sensing element may be a diode configured to have a depletion region, and in some embodiments discussed herein, the term “sensing element” may exclude an avalanche diode operating in Geiger mode. A detector element may include a diode, an interconnect, and a circuit, which may include front-end electronics, for example. Furthermore, the term “frame” may include or cover “sampling period,” “SEM image pixel period,” or “pixel period,” etc. A SEM image frame may refer to a frame of pixels that may be refreshed on a frame-by-frame basis, while a data frame may refer to a group of data acquired by a detection system within a specified period of time.

Embodiments of the present disclosure may utilise a detection method that involves charged particle counting, e.g. electron counting. By counting the number of electrons received during a pre-defined period, the intensity of an incoming electron beam may be determined. The term “incoming electron” may include or cover an incident electron, such as an electron that impacts the surface of a detector. According to some embodiments, noise from the charged particle detection process may be reduced. However, solely improving SNR may not fulfill the ever-increasing needs of various SEM applications.

Electron counting may involve determining individual electron arrival events occurring at a detector. For example, electrons may be detected one-by-one as they reach the detector. In some embodiments, electrons incident on a detector may generate an electrical signal that is routed to an electro-optic modulator that selectively modulates a light beam, by changing a parameter thereof such as phase, amplitude or polarization. Signal processing circuitries detect the modulation of the light beam and then read-out to an interface, such as a digital controller. A detector may be configured to resolve signals generated by incident electrons and distinguish individual electrons with a discrete count.

In some embodiments, electron counting may be applied to situations in which beam current is very small. For example, an electron beam may be set to irradiate a sample with a low dose. Low current may be used to prevent oversaturation of an electron counting detector by large current. For example, large current may have the effect of introducing nonlinearity in detection results. Meanwhile, for a detector that may be used in an industrial setting, the detector should also be able to handle situations of large beam current.

Some embodiments may utilize a detector having a plurality of relatively small sensing elements that may be used to detect an electron beam. Isolation may be provided between adjacent sensing elements so that the probability of one incoming electron going from one sensing element to its adjacent sensing elements may be reduced. In this way, crosstalk between adjacent sensing elements may be reduced.

In some embodiments, a detector may be constructed using digital circuitry and opto-electronic elements rather than implementations requiring a large amount of analog or digital electronic circuits. Accordingly, various aspects of implementation of a detector, such as operating speed, may be improved.

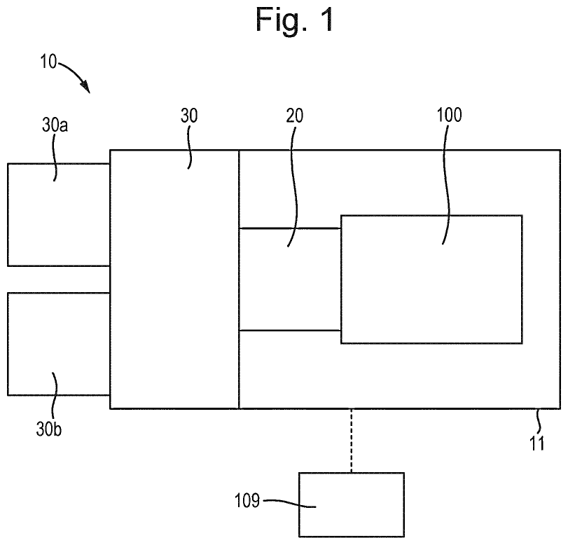

Reference is now made to FIG. 1, which illustrates an exemplary electron beam inspection (EBI) system 10 that may include a detector, consistent with embodiments of the present disclosure. EBI system 10 may be used for imaging. As shown in FIG. 1, EBI system 10 includes a main chamber 11 a load/lock chamber 20, an electron beam tool 100, and an equipment front end module (EFEM) 30. Electron beam tool 100 is located within main chamber 11. EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples may be collectively referred to as “samples” herein).

One or more robotic arms (not shown) in EFEM 30 may transport the wafers to load/lock chamber 20. Load/lock chamber 20 is connected to a load/lock vacuum pump system (not shown) which removes gas molecules in load/lock chamber 20 to reach a first pressure below the atmospheric pressure. After reaching the first pressure, one or more robotic arms (not shown) may transport the wafer from load/lock chamber 20 to main chamber 11. Main chamber 11 is connected to a main chamber vacuum pump system (not shown) which removes gas molecules in main chamber 11 to reach a second pressure below the first pressure. After reaching the second pressure, the wafer is subject to inspection by electron beam tool 100. Electron beam tool 100 may be a single-beam system or a multi-beam system. A controller 109 is electronically connected to electron beam tool 100 and may be electronically connected to other components as well. Controller 109 may be a computer configured to execute various controls of EBI system 10. While controller 109 is shown in FIG. 1 as being outside of the structure that includes main chamber 11, load/lock chamber 20, and EFEM 30, it is appreciated that controller 109 can be part of the structure.

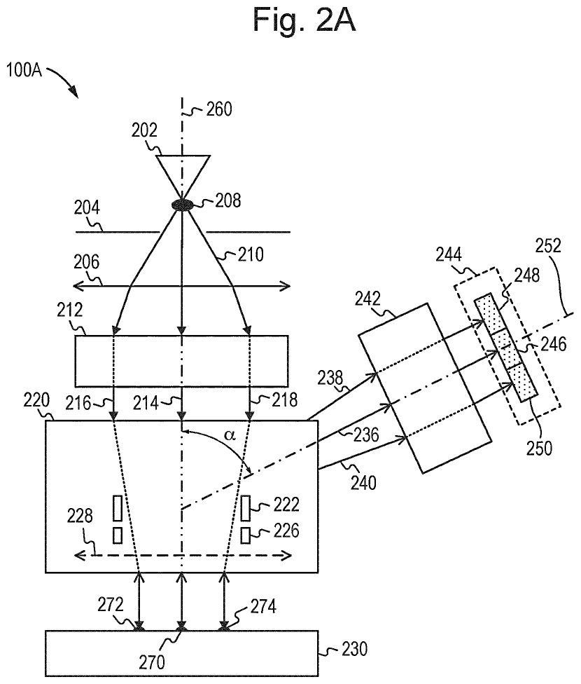

FIG. 2A illustrates a charged particle beam apparatus in which an inspection system may comprise a multi-beam inspection tool that uses multiple primary electron beamlets to simultaneously scan multiple locations on a sample.

As shown in FIG. 2A, an electron beam tool 100A (also referred to herein as apparatus 100A) may comprise an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 2A), multiple secondary electron beams 236, 238, and 240, a secondary optical system 242, and an electron detection device 244. Electron source 202 may generate primary particles, such as electrons of primary electron beam 210. A controller, image processing system, and the like may be coupled to electron detection device 244. Primary projection optical system 220 may comprise a beam separator 222, deflection scanning unit 226, and objective lens 228. Electron detection device 244 may comprise detection sub-regions 246, 248, and 250.

Electron source 202, gun aperture 204, condenser lens 206, source conversion unit 212, beam separator 222, deflection scanning unit 226, and objective lens 228 may be aligned with a primary optical axis 260 of apparatus 100A. Secondary optical system 242 and electron detection device 244 may be aligned with a secondary optical axis 252 of apparatus 100A.

Electron source 202 may comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 may block off peripheral electrons of primary electron beam 210 to reduce size of probe spots 270, 272, and 274.

Source conversion unit 212 may comprise an array of image-forming elements (not shown in FIG. 2A) and an array of beam-limit apertures (not shown in FIG. 2A). An example of source conversion unit 212 may be found in U.S. Pat. No. 9,691,586; U.S. Publication No. 2017/0025243; and International Application No. PCT/EP2017/084429, all of which are incorporated by reference in their entireties. The array of image-forming elements may comprise an array of micro-deflectors or micro-lenses. The array of image-forming elements may form a plurality of parallel images (virtual or real) of crossover 208 with a plurality of beamlets 214, 216, and 218 of primary electron beam 210. The array of beam-limit apertures may limit the plurality of beamlets 214, 216, and 218.

Condenser lens 206 may focus primary electron beam 210. The electric currents of beamlets 214, 216, and 218 downstream of source conversion unit 212 may be varied by adjusting the focusing power of condenser lens 206 or by changing the radial sizes of the corresponding beam-limit apertures within the array of beam-limit apertures. Condenser lens 206 may be a moveable condenser lens that may be configured so that the position of its first principle plane is movable. The movable condenser lens may be configured to be magnetic, which may result in off-axis beamlets 216 and 218 landing on the beamlet-limit apertures with rotation angles. The rotation angles change with the focusing power and the position of the first principal plane of the movable condenser lens. In some embodiments, the moveable condenser lens may be a moveable anti-rotation condenser lens, which involves an anti-rotation lens with a movable first principal plane. A moveable condenser lens is further described in U.S. Publication No. 2017/0025241, which is incorporated by reference in its entirety.

Objective lens 228 may focus beamlets 214, 216, and 218 onto a wafer 230 for inspection and may form a plurality of probe spots 270, 272, and 274 on the surface of wafer 230.

Beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. Beam separator 222 may separate secondary electron beams 236, 238, and 240 from beamlets 214, 216, and 218 and direct secondary electron beams 236, 238, and 240 towards secondary optical system 242.

Deflection scanning unit 226 may deflect beamlets 214, 216, and 218 to scan probe spots 270, 272, and 274 over a surface area of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 may comprise electrons with a distribution of energies including secondary electrons and backscattered electrons. Secondary optical system 242 may focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of surface area of wafer 230.

Although FIG. 2A shows an example of electron beam tool 100 as a multi-beam tool that uses a plurality of beamlets, embodiments of the present disclosure are not so limited. For example, electron beam tool 100 may also be a single-beam tool that uses only one primary electron beam to scan one location on a wafer at a time.

As shown in FIG. 2B, an electron beam tool 100B (also referred to herein as apparatus 100B) may be a single-beam inspection tool that is used in EBI system 10. Apparatus 100B includes a wafer holder 136 supported by motorized stage 134 to hold a wafer 150 to be inspected. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In an imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered primary particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 100B through a medium such as an electrical conductor, optical fiber cable, portable storage media, IR, Bluetooth, Internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses are used for controlling the electron beam. For example, first quadrupole lens 148 can be controlled to adjust the beam current and second quadrupole lens 158 can be controlled to adjust the beam spot size and beam shape.

FIG. 2B illustrates a charged particle beam apparatus in which an inspection system may use a single primary beam that may be configured to generate secondary electrons by interacting with wafer 150. Detector 144 may be placed along optical axis 105, as in the example shown in FIG. 2B. The primary electron beam may be configured to travel along optical axis 105. Accordingly, detector 144 may include a hole at its center so that the primary electron beam may pass through to reach wafer 150. However, some embodiments may use a detector placed off-axis relative to the optical axis along which the primary electron beam travels. For example, as in the example shown in FIG. 2A, beam separator 222 may be provided to direct secondary electron beams toward a detector placed off-axis. Beam separator 222 may be configured to divert secondary electron beams by an angle α.

Another example of a charged particle beam apparatus will now be discussed with reference to FIG. 2C. Electron beam tool 100C (also referred to herein as apparatus 100C) may be an example of electron beam tool 100 and may be similar to electron beam tool 100A shown in FIG. 2A.

As shown in FIG. 2C, beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. For a dispersion plane 224 of beam separator 222, FIG. 2C shows dispersion of beamlet 214 with nominal energy V0 and an energy spread ΔV into beamlet portions 262 corresponding to energy V0, beamlet portion 264 corresponding to energy V0+ΔV/2, and beamlet portion 266 corresponding to energy V0-ΔV/2. The total force exerted by beam separator 222 on an electron of secondary electron beams 236, 238, and 240 can be non-zero. Beam separator 222 may separate secondary electron beams 236, 238, and 240 from beamlets 214, 216, and 218 and direct secondary electron beams 236, 238, and 240 towards secondary optical system 242.

A semiconductor electron detector (sometimes called a “PIN detector”) may be used in apparatus 100 in EBI system 10. EBI system 10 may be a high-speed wafer imaging SEM including an image processor. An electron beam generated by EBI system 10 may irradiate the surface of a sample or may penetrate the sample. EBI system 10 may be used to image a sample surface or structures under the surface, such as for analyzing layer alignment. In some embodiments, EBI system 10 may detect and report process defects relating to manufacturing semiconductor wafers by, for example, comparing SEM images against device layout patterns, or SEM images of identical patterns at other locations on the wafer under inspection. A PIN detector may include a silicon PIN diode that may operate with negative bias. A PIN detector may be configured so that incoming electrons generate a relatively large and distinct detection signal. In some embodiments, a PIN detector may be configured so that an incoming electron may generate a number of electron-hole pairs while a photon may generate just one electron-hole pair. A PIN detector used for electron counting may have numerous differences as compared to a photodiode used for photon detection, as shall be discussed as follows.

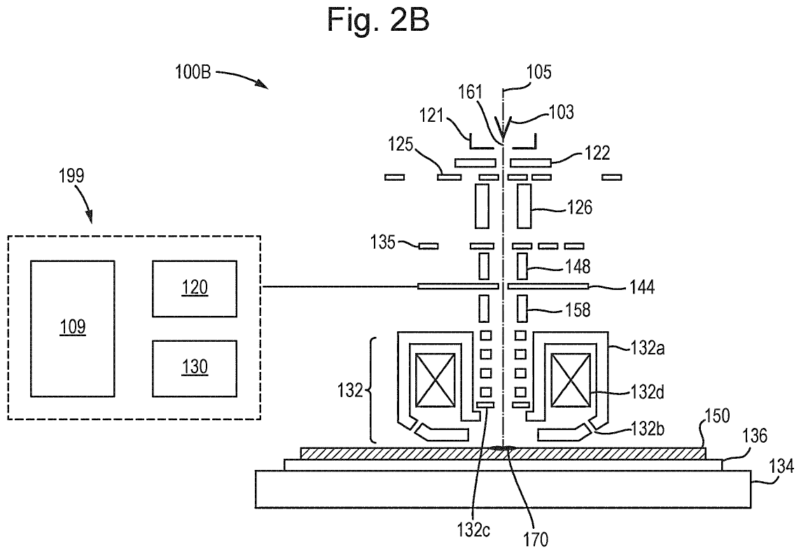

Reference is now made to FIG. 3, which illustrates a schematic representation of an exemplary structure of a detector 300. Detector 300 may be provided as detector 144 or electron detection device 244 with reference to FIG. 2A, FIG. 2B, and FIG. 2C.

Detector 300 may comprise an array of sensing elements, including sensing elements 311, 312, and 313. There may be a large number of sensing elements, e.g. 1,000 or more, desirably 5,000 or more, more desirably 10,000 or more. The sensing elements may be arranged in a planar, two-dimensional array, the plane of the array being substantially perpendicular to an incidence direction of incoming charged particles. In some embodiments, detector 300 may be arranged so as to be inclined relative to the incidence direction. The array may comprise 10 or more rows, desirably 50 or more rows, more desirably 100 or more rows, with each row comprising 10 or more sensing elements, desirably 50 or more sensing elements, more desirably 100 or more sending elements. While one array is shown in FIG. 3, it is appreciated that detector 300 may include multiple arrays, such as one array for each secondary electron beam.

Detector 300 may comprise a substrate 310. Substrate 310 may be a semiconductor substrate that may include the sensing elements. A sensing element may be a diode. A sensing element may also be an element similar to a diode that can convert incident energy into a measurable signal. The sensing elements may comprise, for example, a PIN diode, an avalanche diode, an electron multiplier tube (EMT), etc., or combinations thereof. An area 325 may be provided between adjacent sensing elements. Area 325 may be an isolation area to isolate the sides or corners of neighboring sensing elements from one another. Area 325 may comprise an insulating material that is a material different from that of other areas of the detection surface of detector 300. Area 325 may be provided as a cross-shaped area as seen in the plane view of FIG. 3. Area 325 may be provided as a square. In some embodiments, area 325 may not be provided between adjacent sides of sensing elements. For example, in some embodiments, there may be no isolation area provided on a detection surface of a detector.

Sensing elements may generate an electric signal commensurate with charged particles received in the active area of a sensing element. For example, a sensing element may generate an electric current signal commensurate with the energy of a received electron. A pre-processing circuit may convert the generated current signal into a voltage that may represent the intensity of an electron beam spot or a part thereof. The pre-processing circuitry may comprise, for example, pre-amp circuitries. Pre-amp circuitries may include, for example, a charge transfer amplifier (CTA), a transimpedance amplifier (TIA), an impedance conversion circuit coupled with a CTA or a TIA or a three-transistor amplifier. In some embodiments, signal processing circuitry may be provided that provides an output signal in arbitrary units on a timewise basis. There may be provided one or a plurality of substrates, such as dies, that may form circuit layers for processing the output of sensing elements. The dies may be stacked together in a thickness direction of the detector. Other circuitries may also be provided for other functions. For example, switch actuating circuitries may be provided that may control switching elements for connecting sensing elements to one another.

Sensing elements are desirably configured to be individually switchable between an active state and an inactive state. In an inactive state, a sensing element does not emit an output when a charged particle is incident thereon. A sensing element may be set to an inactive state by, for example, turning of a power supply to an amplifier associated with or incorporated into the sensing element. A sensing element may be set to an inactive state by, for example, blocking a signal that would otherwise be output therefrom.

Although the figures may show sensing elements 311, 312, and 313 as discrete units, such divisions may not actually be present. For example, the sensing elements of a detector may be formed by a semiconductor device constituting a PIN diode device. The PIN diode device may be manufactured as a substrate with a plurality of layers including a p-type region, an intrinsic region, and an n-type region. One or more of such layers may be contiguous in cross-sectional view. In some embodiments, however, sensing elements may be provided with physical separation between them. Further layers may also be provided in addition to the sensor layer, such as a circuit layer, and a read-out layer, for example.

As one example of a further layer, detector 300 may be provided with one or more circuit layers adjacent to the sensor layer. The one or more circuit layers may comprise line wires, interconnects, and various electronic circuit components. The one or more circuit layers may comprise a processing system. The one or more circuit layers may comprise signal processing circuitries. The one or more circuit layers may be configured to receive the output current detected from sensing elements in the sensor layer. The one or more circuit layers and the sensor layer may be provided in the same or separate dies, for example.

Further details of the operation of a detection element, such as a diode, for detection of electrons can be found in US2019/0378682A1, which document is hereby incorporate by reference in its entirety. As an alternative to PIN diodes, embodiments may employ Low Gain Avalanche diodes (LGAD).

Each of the sensing elements 311, 312, 313 outputs an electrical signal, which may be referred to as a detection signal, in response to an incident charged particle, specifically an electron. The detection signal may be, for example, a signal in amperes, volts, or arbitrary units commensurate with energy of electrons received at the respective sensing element. In some embodiments, the detection signal may represent the number of charged particles incident on sensing elements of the detector within a time period, e.g. a frame. The detection signal may indicate that a discrete number of charged particles has arrived at a sensing element. The number of charged particles may be discerned as a whole number.

The radiation receiving part of the sensing element, e.g. the PIN diode, may emit a brief pulse of current when a charged particle is incident. The sensing element may therefore include a persistent element, such as an accumulator or sample and hold circuit, that is set to an “on” state by the pulse of current or accumulates charge in response to the pulse of current until reset by a reset circuit at the end of a sampling period or frame. The sampling period or frame rate may be set in advance or automatically determined on the basis of operating conditions.

Each sensing element 311, 312, 313 is connected to electronic circuitry and/or electro-optic devices (not shown) that combine the outputs to produce a detector output signal for each detector 300. An electro-optic arrangement for summing the outputs of an array of sensing elements is described in European Patent Application number EP22186172.7, filed 21 Jul. 2022, which document is hereby incorporated by reference at least in relation to the disclosure therein of an electro-optic signal summing arrangement. The detector output signal may be a simple sum of the detection signals output by all the sensing elements. In some embodiments, a weighted sum can be desirable and is achieved by introducing a weighting factor for each sensing element. The weighting factor may, for example vary between 0 and 1. A weighting factor can be implemented in several different ways. For example, the weighting factor may be applied to the gain of an electronic amplifier associated with each sensing element. The per-sensing element weighting factors may be fixed at the time of manufacture or calibration or may be variable during use of the device.

In some embodiments, a beam spot on a detector surface may be larger than a beam spot on a sample surface. Accordingly, the overall size of a detection surface of a detector may be configured to be large enough to accommodate a broad beam spot. The beam spot on the detector surface may be on the order of a few millimeters in diameter. However, increasing a size of a detector may contribute to noise effects. For example, the capacitance of a detector may be proportional to an area of a detector surface. Some sources of noise, such as that due to components being coupled to a detector (e.g., an amplifier), may be related to capacitance.

In some embodiments, an area ratio, which may be the ratio of area of an individual sensing element to that of the entire surface of a detector, may be varied. The area ratio may have a corresponding relationship to SNR. For example, in some embodiments, decreasing the size of a sensing element to be 1/1,000 of the area of a detector may correspond to a 1,000× increase in SNR.

The array of sensing elements may include a plurality of sensing elements each having dimensions of Dx and Dy, or less, for example. For example, each of the sensing elements may have a radiation receiving area having a size no more than 500 μm by 500 μm, desirably no more than 200 μm by 200 μm, more desirably no more than 150 μm by 150 μm, even as small as 50 μm by 50 μm. In some embodiments, the radiation detector may comprise no less than 1,000 sensing elements, desirably no less than 5,000 sensing elements, more desirably no less than 10,000 sensing elements. The sensing elements may be arranged in a planar, two-dimensional array, the plane of the array being substantially perpendicular to an incidence direction of incoming charged particles. In some embodiments, the detector may be arranged so as to be inclined relative to the incidence direction.

In many use cases, the topographic signal obtained from a sample (i.e. a signal that is dependent on the topography of the sample) is generally contained in the secondary electrons. The measured backscattered electrons captured by conventionally-sized detectors are only weakly Therefore the backscattered electrons may be considered noise. dependent on topography. Conventional detectors cannot both distinguish between secondary and backscattered electrons and provide information as to the location of incidences so the detector output signal has a lower signal to noise ratio, and also contrast to noise ratio, than would be possible if backscattered electrons could be excluded. Proposals have been made for detectors that can distinguish backscattered electrons from secondary electrons by their energy but these are not presently practicable.

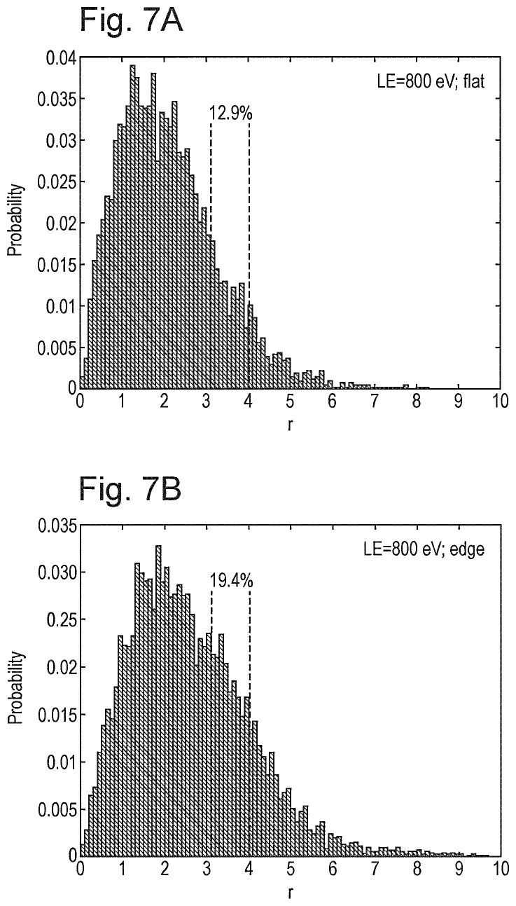

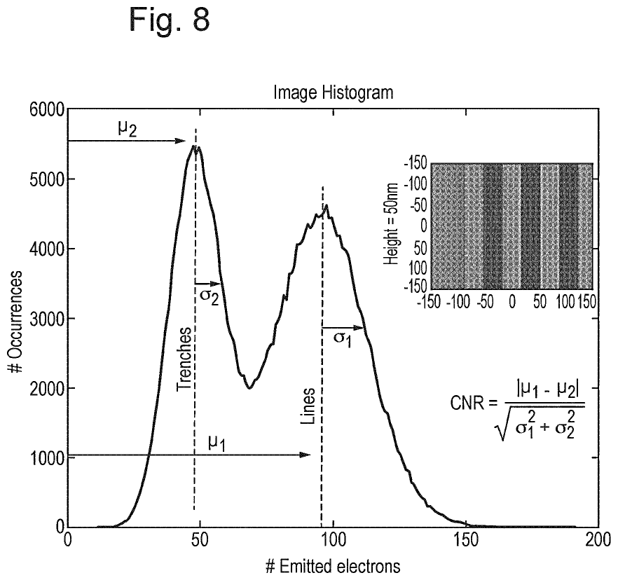

The contrast to noise ratio metric (CNR) is explained with reference to FIGS. 8 and 9. A histogram (FIG. 8) of an image of a region of a substrate obtained using a charged particle assessment apparatus may have two peaks derived from two feature types, e.g. lines and trenches or flats and edges. The contrast to noise ratio is defined as:

$$CNR = \frac{\vert {μ}_{1} - {μ}_{2} \vert}{\sqrt{{σ}_{1}^{2} - {σ}_{2}^{2}}}$$

where μ₁ and μ₂ are the signal levels (e.g. incident electron counts) of the respective peaks and σ₁ and σ₂ are the half-widths at half maximum of the respective peaks, representing noise in the image. FIG. 9 is a sketch of an edge topography and corresponding secondary electron yield. Values for μ and σ are obtained from image parts correspond to the edge and to flat regions. Other metrics measuring the contrast of an image can be used and would also likely be improved by exclusion of backscattered electrons.

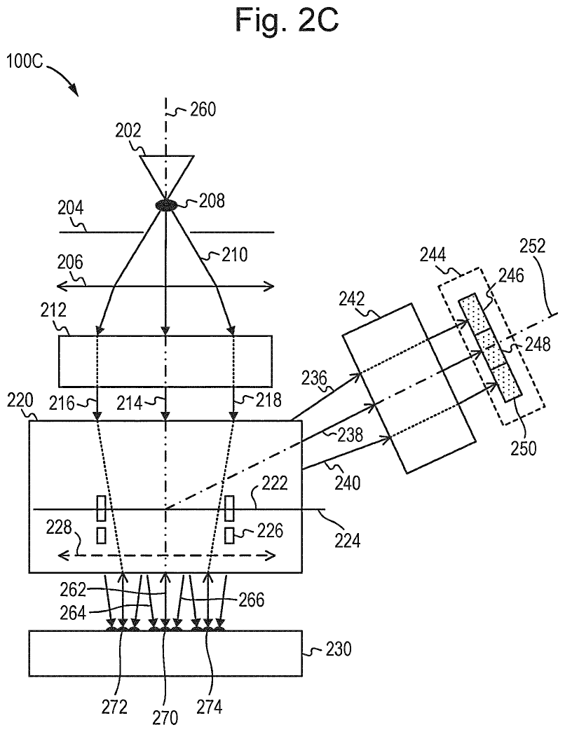

The present inventors have found in simulations that the incidence locations of backscattered electrons and secondary electrons on a detector are different. Secondary electrons hit the detector close to its center, while backscattered electrons impinge over a much larger detector area, as shown in FIGS. 4A to 4C, which show simulated incidence locations of secondary and backscattered electrons on a detector plane. Landing energy at the sample (LE) was 800 eV. FIG. 4A shows secondary electron and backscattered electron incidences together. FIG. 4B shows only secondary electron incidences (energy leaving the sample<50 eV). FIG. 4C shows only backscattered electrons incidences (energy>50 eV).

It has also been found from the same simulations that the secondary electron incidence area depends on landing energy at the sample, with a smaller energy leading to a smaller incidence area. Moreover, it was found that the secondary electron distribution is spread over a slightly larger area when scanning across an edge topography on the sample compared to a flat topography. Thus, the spatial distribution of secondary electrons is topography-dependent.

Accordingly, with a charged particle detector having an array of sensing elements configured to generate an electrical signal in response to incident charged particles from a sample, it is proposed to provide a controller configured to selectively activate a first subset of the set of sensing elements and to combine the electrical signals of the first subset into a detector output signal. The first subset is selected, based on predicted distributions of backscattered and secondary charged particles (e.g. electrons) to achieve a desired effect. Based on a predicted distribution of backscattered and/or secondary particles, it is possible to determine by simple calculation, the predicted ratio of backscattered to secondary particles incident on a given sensing element or subset of the sensing elements. Therefore, it is possible to select sensing elements for activation or deactivation based on criteria relating to the predicted ratio of backscattered to secondary particles. Several different effects can be achieved according to the size, shape and location of the region(s) of the detector defined by the selected subset.

A second subset of sensing elements that are not part of the first subset can be deactivated, i.e. their outputs are not combined into the detector output signal. Desirably sensing elements of the second subset are turned off, which is advantageous in that it reduces energy consumption and heat dissipation in the main vacuum chamber. A sensing element can be turned off by deactivating a power supply to the sensing element, e.g. to an amplifier associated with or incorporated in the sensing element.

The controller may be integrated into the detector or positioned elsewhere in the assessment apparatus. Integrating the controller in the detector may be desirable as it reduces the amount of data that needs to be transmitted from the detector. The controller may be configured to operate in various different modes, or combinations of modes, as described below.

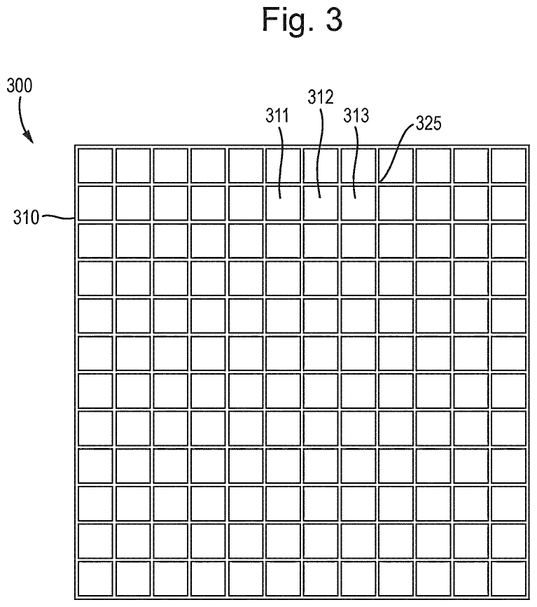

For example, by selecting a subset of sensing elements corresponding to a variable inner part of the array of sensing elements (e.g. selecting as the first subset sensing elements that are within a selected radius of the detector reference point) as a secondary electron detector, and optionally an outer part as a backscattered electron detector, as shown in FIG. 5, different effects can be achieved. For example, in a contrast mode it is possible to achieve a desired contrast to noise ratio for the detector output signal and in a ratio mode a desired ratio of detection of secondary particles to backscattered particles can be achieved. By way of example, three different criteria to select the radius of the secondary electron detector will be described below.

In a first example of an inward annular mode, the secondary electron detector area is selected to follow the secondary electron incidence area. The detector may be designed such that the full detector area captures more than 90% of all secondary electrons incidences at the highest landing energy at the sample that the charged particle assessment system is capable of. At lower landing energies the radius of the secondary electron incidence area will be reduced, and so it is possible to select as the first subset a secondary electron detector area that is smaller than the whole array of sensing elements but still sufficiently large that a predetermined proportion (e.g. >95%) of the secondary electrons incidences are captured. This may mean a substantial reduction in the area of the array of sensing elements that is activated, e.g. only the sensing elements within a radius rᵢ are activated where rᵢ is approximately 1/10 of the radius of the whole array (denoted rₐ) for low landing energies (e.g. LE=150 eV). This enables detection of secondary electrons with reduced background of backscattered electrons. In some embodiments, the radius of the region occupied by the selected subsets less than 75% of the radius of the whole array, desirably less than 50%, more desirably less than 20%.

As depicted in FIG. 5, in an inward annular mode the array of sensing elements is controlled to select an inner detector part 331 that primarily detects secondary electrons as the active subset of the array of sensing elements, while the outer detector part 332 detects backscattered electrons. The separation of secondary electron detector and backscattered electron detector stems purely from the different incidence locations of backscattered electrons and secondary electrons; no further separation/selection methods (e.g. energy selection) are included. It is to be noted in this example that the inner detector part is a circle (or a pixelated approximation of a circle) centered on the center of the array of sensing elements. However, if for any reason the distribution of secondary electrodes is not centered on the center of the array of sensing elements, the inner detector part may be centered on another predetermined position, referred to as the detector reference point. For example, the detector reference point may be a center of an impact region of particles on the detector. The same applies for other selected areas as described below.

The signal from the outer detector part consists only of backscattered electron incidences. In an outward annular mode it may be processed separately from the signal of the secondary electrons detector pixels if it is considered valuable (e.g. for diagnostic purposes). Alternatively, this part of the detector may be turned off. Turning off, or deactivating, sensing elements that are not part of the selected subset can be advantageous in that it reduces energy consumption and heat dissipation in the main vacuum chamber. A sensing element may be deactivated by deactivating a power supply to the sensing element, e.g. to an amplifier associated with or incorporated in the sensing element.

A variation of an inward annular mode is to select the secondary electrons detector area so as to achieve at least a desired ratio secondary particles to backscattered particles and thereby minimize the contribution of backscattered electron incidences. This may entail a slight reduction in the number of secondary electron incidences (no longer>90-95% of all secondary electrons are captured) but will reduce backscattered electron noise and therefore (after longer integration time) better contrast. This mode of operation may be beneficial for low contrast use cases for which there is currently no suitable SEM assessment tool. If contrast is increased, critical dimensions can be measured more accurately. Alternatively, the throughput of the assessment tool can be increased while maintaining the contrast level.

Determining the area of the array of sensing elements to use to achieve a desired effect such as a desired contrast to noise ratio or a desired ratio of detection of secondary particles to backscattered particles, for example the radius of a dividing line between selected and non-selected sensing elements, can be based on predicted distributions of backscattered and/or secondary particles, e.g. obtained from simulation or empirical data. As discussed further below, in empirically derived particle incidence distributions using test samples, the distribution of particle incidences at large radii from a detector reference point can be used to estimate a distribution of backscattered particles across the whole detector. This estimated distribution of backscattered particles can then be subtracted from the total distribution to obtain an estimated distribution of secondary particles. Another approach, discussed in more detail below, is to scan test samples with feature regions and flat regions to obtain flat and feature particle incidence distributions. Since the incidence distribution of secondary particles is significantly more dependent on topography, the difference between the flat particle incidence distribution and the feature particle incidence distribution can be attributed to secondary particles. Other approaches to determining the predicted distributions of backscattered and/or secondary particles using particle distribution data obtained from test samples or production sample can also be used.

A method of calibration to determine a desired contrast to noise ratio or a desired ratio of detection of secondary particles to backscattered particles involves: scanning a charged particle beam across a calibration sample having a known topography; receiving electrical signals from the sensing elements in response to returning particles generated in response to the charged particle beam to obtain a distribution of returning particles as a function of position on the detector; estimating a distribution of backscattered particles amongst the returning particles as a function of position on the detector; subtracting the distribution of backscattered particles from the distribution of returning particles to obtain a distribution of secondary particles; and selecting a subset of the sensing elements to be used for assessment of a sample based on the distribution of backscattered particles and the distribution of secondary particles.

More specifically, the SEM is used to scan across edges on a calibration wafer with known topography and obtain the full output from the array of sensing elements, including spatial information, for example incidence pixel location for each incidence. From these measurements, the number of incidences with radius R divided by the number of incidences on the whole array is determined. This can be expressed as the percentage of incidences as function of R. The contribution of backscattered electrons to all incidences is estimated based on the rate of increase of incidence with R at larger radii. Outside a certain radius it is assumed that all incidences are backscattered electrons and it is therefore expected that as a function of R the incidences first increase rapidly (SE and BSE contributions), while for R larger than the SE radius the increase of incidences with R is slower. It is therefore expected that the maximum radius at which SEs still contribute can be seen as a change in the slope of the curve of incidences as a function of detector radius. It is assumed, based on Monte Carlo simulations of detector incidence locations, that the distribution of backscattered incidences at small radii is consistent with the distribution of backscattered electrons at larger radii so that by subtracting the estimated backscattered electron distribution from the total distribution, it is possible to obtain the secondary electron distribution as function of R. It is then straightforward to select a radius which captures a desired proportion of the secondary electrons or a desired ratio of backscattered to secondary electrons.

Another mode of operation is an annular mode wherein sensing elements in an annular region of the array of sensing elements are selected. Two effects can be achieved in this way: to obtain a desired ratio of detection of secondary particles to backscattered particles (an example of ratio mode) or to select a subset of the sensing elements to enhance sensitivity to a specific feature type on the sample, e.g. an edge, (an example of sensitivity mode).

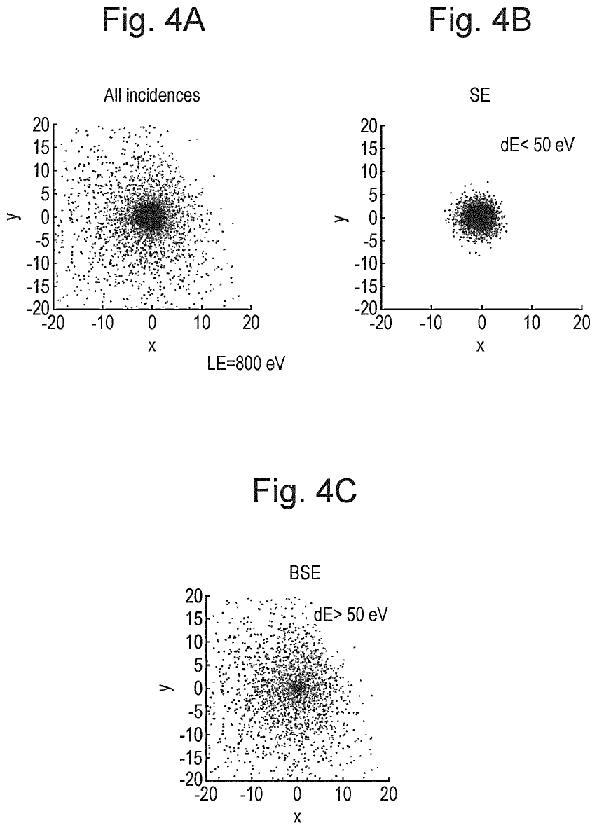

For obtaining a desired ratio of detection of secondary particles to backscattered particles, it can be helpful to deactivate sensing elements in a small central region of the array of sensing elements, as depicted in FIG. 6A. This arrangement excludes the central peak in backscattered electrons and selects only an annular area 333 where the ratio of detected secondary electrons to detected backscattered electrons is high.

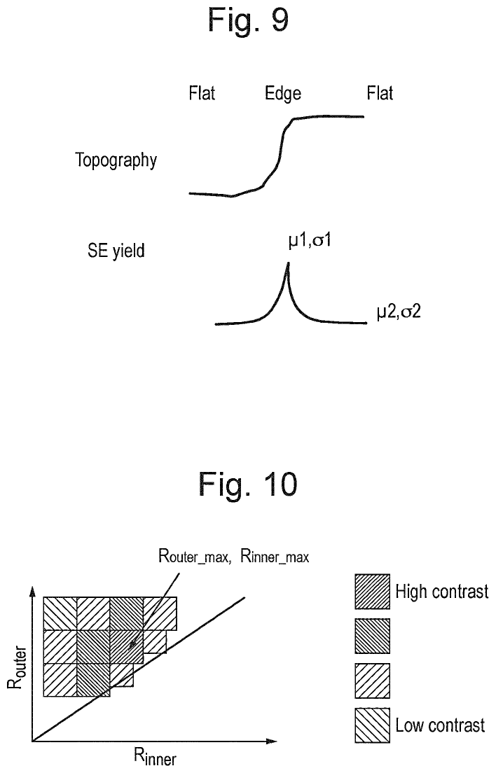

For enhancing sensitivity to a specific feature type on the sample, e.g. an edge, the selected subset can be chosen such that it captures the shift towards larger incidence radius that occurs when scanning across an edge on the sample (instead of a flat surface). For example, a thin annular region 333, e.g. from 3/10 to 4/10 of the radius of the whole array at LE=800 eV, may be selected, as depicted in FIG. 6B. Selection of appropriate values for the inner and outer radii of the active region of the array is explained with reference to FIG. 10. Based on incidence data for all sensing elements of the array obtained in a calibration process, the contrast can be calculated as a function of inner and outer radii values and a pair of values giving maximum contrast can be selected. An enhanced contrast is obtained, as not only the secondary electrons yield is higher at the sample edge, also the proportion of incidences at the selection radius is larger (e.g. 1.5 times as large). In other words the change in signal between an edge being present under the beam and not present is greatest in this region. Whilst the total number of secondary electrons incidences per unit time (and thus throughput) is reduced, the resulting images will have better contrast.

For enhancing sensitivity to edges, the selected subset may define a region that is one or more parts of an annulus rather than a complete annulus. For example the selected subset may define two parts of an annulus, that is centered on the center of the detector, with sensing elements on the axis parallel to the edge to be detected being excluded from the substrate. Another useful shape is a lune (a concave-convex region bounded by two circular arcs), such as a crescent, or similar such as a bean- or kidney-shape. This type of region captures electron incidences to one side of the center of the sensing array but excludes the center. A region offset to one side may have higher contrast to edges from a lower to higher region whilst a region offset to the other side may have a high contrast to edges from a higher to a lower region of the sample. Two such regions may be used to capture both types of edges.

It will be appreciated that since the individual sensing elements have a finite size, the actual shape of the region occupied by the selected subset will be an approximation to a given mathematical shape. A rule may be applied to determine whether a given sensing element is to be included in the selected subset, for example a sensing element is included if its center is within the mathematically defined optimum region or if a certain percentage of the sensing element is within the optimum region.

As above, determining the area of the array of sensing elements to use to achieve an enhanced sensitivity to a specific feature type on the sample, can be based on simulation or empirical results. A calibration approach may involve scanning a charged particle beam across a calibration sample including the topography of interest (e.g. an edge) and a flat topography; receiving electrical signals from the sensing elements in response to returning particles generated in response to the charged particle beam to obtain a feature distribution of returning particles as a function of position on the detector for the feature topography and a flat distribution of returning particles as a function of position on the detector for the flat topography; and selecting a subset of the sensing elements to be used for assessment of a sample based on the feature distribution and the flat distribution.

More specifically, the SEM is used to scan across edges (as an example of a feature of interest) on a calibration wafer with known topography and obtain the full output from the array of sensing elements, including spatial information, for example incidence pixel location for each incidence. From these measurements, the contrast as function of detection ring radii (or more generally any shape of detector area) is calculated. Contrast will be lower if the selected detector area is smaller; this should, within practical limits, be corrected for as the aim is to increase contrast and a reduction of throughput due to the need for more frame averages is accepted. Then it is straightforward to select radii at which contrast is optimal. FIG. 10 is an exemplary plot of contrast (difference between signal with feature and without) as a function of pixel inner radius Rᵢₙₙₑᵣ and pixel outer radius Rₒᵤₜₑᵣ showing the group of pixels with best contrast and at a position between R_{inner_max} and R_{outer_max}.

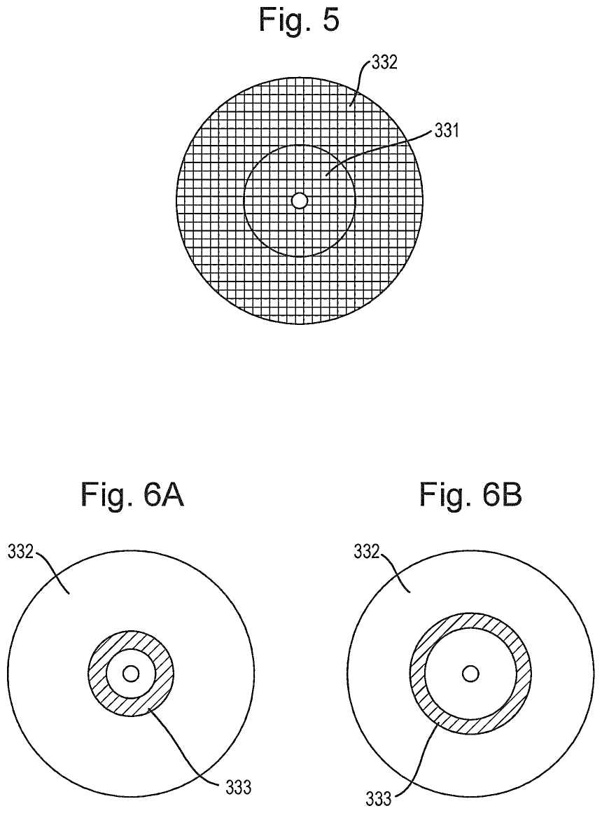

FIGS. 7A and 7B show the distribution of electron incidence on the detector as a function of radius in arbitrary units for a flat sample region (FIG. 7A) and an edge sample region (FIG. 7B). It is seen that at an edge the distribution of the electrons on the detector has a slightly larger radius; the distribution is somewhat broader. The percentage of incidences within a ring between 3 and 4 arbitrary units, increases from 12.9% for a flat sample region to 19.4% at an edge. Thus by selecting the sensing elements within such a ring or annulus as the selected subset the contrast between flat areas and edge areas is enhanced.

Whilst the use of circular, annular, part annular and concave-convex regions of the array of sensing elements as the selected subset has been described above, it will be appreciated that regions of other shapes may be useful in other cases. For example the selected subset may form a region having a shape selected from the group consisting of: a circle, an oval, an annulus, a square, a rectangle, a diamond, a rhombus. An asymmetric region may be useful where the distribution of backscattered or secondary electrons is asymmetric. Likewise, the selected subset of sensing elements need not occupy a single continuous region but may form a plurality of disjoint regions. A suitable subset can be identified using data of incidences on individual sensing elements obtained in calibration scans of specific topologies or through simulation, e.g. using Monte Carlo methods.

While the arrangements described above seek to select secondary electrons in preference to backscattered electrons, it is of course possible to select backscattered electrons in preference to secondary electrons. This can be done by inverting the above-described selections, e.g. select only sensing elements outside a selected radius or deactivate sensing elements with an annular region. This may be useful to enhance contrast (and thus increase throughput) in high landing energy/high voltage SEM applications.

A detector may be configured to operate in several different modes, as selected by the user. The modes may include some or all of: selecting sensing elements only inside a central region, e.g. a circle; selecting sensing elements only outside a central region, e.g. a circle; selecting sensing elements between two boundaries, which may be circular; and selecting sensing elements not between two boundaries, which may be circular.

A variety of results may be acquired according to specific application requirements based on the same set of acquired raw data. Results may be used in post processing rather than in pre-processing. In some embodiments, pre-processing may include sensing element grouping. Data may be further tailored for optimizing specific purposes. For example, a trade-off relationship may exist between optimizing detection parameters such as cross talk and secondary charged particle collection efficiency. However, when post processing is used to adjust data, the trade-off may be adjusted without loss of information. This may provide application layers with more flexibility and may reduce the risk of having to redo specific operations merely to obtain data with different detection parameter settings.

In some embodiments, a detector may communicate with a controller that controls a charged particle beam system. The controller may instruct components of the charged particle beam system to perform various functions, such as controlling a charged particle source to generate a charged particle beam and controlling a deflector to scan the charged particle beam. The controller may also perform various other functions such as adjusting a sampling rate of a detector, resetting sensing element, or performing image processing. The controller may comprise a storage that is a storage medium such as a hard disk, random access memory (RAM), other types of computer readable memory, and the like. The storage may be used for saving scanned raw image data as original images, and post-processed images. A non-transitory computer readable medium may be provided that stores instructions for a processor of controller 109 to carry out charged particle beam detection, sampling period determination, image processing, or other functions and methods consistent with the present disclosure. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a ROM, a PROM, and EPROM, a FLASH-EPROM or any other flash memory, NVRAM, a cache, a register, any other memory chip or cartridge, and networked versions of the same.

Block diagrams in the figures may illustrate the architecture, functionality, and operation of possible implementations of systems, methods, and computer hardware/software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

Exemplary embodiments of the invention are set out in the following numbered clauses:
1. A method of configuring a detector of a charged particle assessment system, the detector having an array of sensing elements configured to generate electrical signals in response to incident secondary particles or backscattered particles from a sample, the method comprising:
   selecting a first subset of the set of sensing elements for activation based on data derived from a predicted distribution of secondary particles or backscattered particles; and
   selecting a second subset of the set of sensing elements for deactivation based on the predicted distribution;
   wherein the first subset has a different predicted ratio of incident secondary particles to incident backscattered particles than the second subset.
2. The method according to clause 1 wherein the first subset is selected to have a higher predicted ratio of incident secondary particles to incident backscattered particles than the second subset.
3. The method according to clause 1 wherein the first subset is selected to have a predicted ratio of incident secondary particles to incident backscattered particles higher than a predetermined ratio.
4. The method according to clause 1 wherein the first subset is selected to capture at least a predetermined proportion of secondary particles incident from the sample.
5. The method of clause 2, 3 or 4 wherein the first subset consists of sensing elements within a selected radius of a detector reference point, desirably a center of an impact region of particles on the detector and the second subset consists of sensing elements outside the selected radius of the detector reference point.
6. The method according to clause 1 wherein the first subset is selected to have a higher sensitivity to a predetermined feature type on the sample than the second subset.
7. The method of clause 6 wherein the first subset consists of sensing elements within a selected maximum radius of a detector reference point, desirably a center of an impact region of particles on the detector, and outside a selected minimum radius of the detector reference point and the second subset consists of sensing elements outside the selected maximum radius of the detector reference point and sensing elements within a selected minimum radius of the detector reference point.
8. The method of any of clauses 1 to 4 or 6 wherein the first subset consists of sensing elements that form a shape selected from the group consisting of: a circle, an oval, an annulus, a square, a rectangle, a diamond, a rhombus, a concave-convex shape.
9. The method of any of clauses 1 to 4 or 6 wherein the first subset consists of sensing elements that form a plurality of disjoint regions.
10. The method of any of clauses 1 to 9 further comprising obtaining the predicted distribution of secondary particles or backscattered particles by performing simulations of directing a charged particle beam at a sample.
11. The method of any of clauses 1 to 10 further comprising obtaining the predicted distribution of secondary particles or backscattered particles by analysis of empirical results of directing a charged particle beam onto at least one sample.
12. A method of detecting charged particles comprising:
   configuring a detector of a charged particle assessment system by the method of any of clauses 1 to 9;
   directing a charged particle beam onto a sample using the charged particle assessment system so that secondary particles and backscattered particles are generated in response to the charged particle beam;
   directing the secondary particles and backscattered particles to the detector;
   activating the first subset of the array of sensing elements;
   combining the electrical signals of the first subset into a detector output signal; and
   deactivating the second subset of the array of sensing elements.
13. A non-transitory computer-readable medium including a set of instructions that is executable by one or more processors of a controller to cause the controller to control a charged particle assessment system to perform a method according to any of the preceding clauses.
14. A charged particle assessment system comprising:
   a charged-particle beam apparatus configured to direct a charged particle beam onto a sample so that secondary particles and backscattered particles are generated in response to the charged particle beam;
   an array of sensing elements configured to generate electrical signals in response to incident secondary particles or backscattered particles from the sample; and
   a controller configured to selectively activate a first subset of the set of sensing elements, to selectively deactivate a second subset of the set of sensing elements and to combine the electrical signals of the selected subset into a detector output signal, wherein the selective activation and selective deactivation are based on a predicted distribution of secondary particles or backscattered particles.
15. The charged particle assessment system of clause 14 wherein the controller is further configured to operate in a ratio mode wherein the selected subset is selected to achieve a desired ratio of detection of secondary particles to backscattered particles across the array of sensing elements.
16. The charged particle assessment system of clause 14 or 15 wherein the controller is further configured to operate in a contrast mode wherein the selected subset is selected to achieve a desired contrast to noise ratio for the detector output signal.
17. The charged particle assessment system of clause 14, 15 or 16 wherein the controller is further configured to operate in a sensitivity mode wherein the selected subset is selected to achieve a desired sensitivity to features, e.g. edges, on the sample.
18. The charged particle assessment system of clause 14, 15, 16 or 17 wherein the controller is further configured to operate in an inward radial mode wherein the selected subset consists of sensing elements within a selected radius of a detector reference point, desirably a center of an impact region of particles on the detector.
19. The charged particle assessment system of one of clauses 14 to 18 wherein the controller is further configured to operate in an outward radial mode wherein the selected subset consists of sensing elements outside a selected radius of a detector reference point, desirably a center of an impact region of particles on the detector.
20. The charged particle assessment system of one of clauses 14 to 19 wherein the controller is further configured to operate in an annular radial mode wherein the selected subset consists of sensing elements within a selected maximum radius of a detector reference point, desirably a center of an impact region of particles on the detector, and outside a selected minimum radius of the detector reference point.
21. The charged particle assessment system of any of clauses 14 to 20 wherein the controller is further configured to operate in a shape mode wherein the selected subset consists of sensing elements that form a shape selected from the group consisting of: a circle, an oval, an annulus, a square, a rectangle, a diamond, a rhombus, a concave-convex shape.
22. The charged particle assessment system of any of clauses 14 to 21 wherein the controller is further configured to operate in a disjoint mode wherein the selected subset consists of sensing elements that form a plurality of disjoint regions.
23. The charged particle assessment system of any of clauses 14 to 22 wherein the controller is configured to deactivate sensing elements not included in the selected subset.
24. The charged particle assessment system of clause 23 wherein the controller is configured to deactivate a power supply to sensing elements not included in the selected subset.
25. The charged particle assessment system of any of clauses 14 to 24 wherein the controller is configured to apply a respective weight to each of the electrical signals to combine the electrical signals into the detector output signal, desirably electrical signals from sensing elements not included in the selected subset having a zero weight.
26. The charged particle assessment system of any of clauses 14 to 25 wherein the charged-particle beam apparatus is configured to direct a plurality of charged particle beams onto the sample; and comprising an array of sensing elements for each of the plurality of charged particle beams.
27. A method of calibrating a charged particle detector in a charged particle assessment apparatus, the charged particle detector having an array of sensing elements that are configured to generate electrical signals in response to incident secondary particles or backscattered particles from the sample; the method comprising:
   scanning a charged particle beam across a calibration sample having a known topography;
   receiving electrical signals from the sensing elements in response to secondary particles and backscattered particles generated in response to the charged particle beam to obtain a combined distribution of secondary particles and backscattered particles as a function of position on the detector; estimating a distribution of backscattered particles amongst the secondary particles and backscattered particles as a function of position on the detector;
   subtracting the distribution of backscattered particles from the combined distribution of secondary particles and backscattered particles to obtain a distribution of secondary particles; and
   selecting a subset of the sensing elements to be used for assessment of a sample based on the distribution of backscattered particles and the distribution of secondary particles.
28. A method according to clause 27 wherein estimating a distribution of backscattered particles is based on the distribution of returning particles at the periphery of the array of sensing elements.
29. A method according to clause 27 or 28 wherein selecting a subset of the sensing elements comprises selecting a subset of the sensing elements to achieve detection of a desired proportion of secondary particles.
30. A method of calibrating a charged particle detector in a charged particle assessment apparatus, the charged particle detector having an array of sensing elements that are configured to generate electrical signals in response to incident secondary particles or backscattered particles from the sample; the method comprising:
   scanning a charged particle beam across a calibration sample including a feature of interest (e.g. an edge) and a flat topography;
   receiving electrical signals from the sensing elements in response to returning particles generated in response to the charged particle beam to obtain a feature distribution of returning particles as a function of position on the detector for the feature topography and a flat distribution of returning particles as a function of position on the detector for the flat topography; and
   selecting a subset of the sensing elements to be used for assessment of a sample based on the feature distribution and the flat distribution.
31. A method according to clause 30 wherein selecting a subset of the sensing elements comprises selecting a subset of the sensing elements to achieve a desired contrast ratio for the feature of interest.

It will be appreciated that the present invention is not limited to the exact construction that has been described above and illustrated in the accompanying drawings, and that various modifications and changes can be made without departing from the scope thereof. For example, while a PIN diode has been discussed with reference to certain exemplary embodiments, other types of diodes, such as a NIP diode may be similarly applied. Furthermore, other types of devices that may generate a measurable signal in response to receiving incident energy may be applied in a detector.

It will be understood that elements shown in separate figures may be combined.

Furthermore, while scanning electron microscopy has been discussed with reference to some embodiments, other types of systems may be applicable as well. For example, a detector may be used in transmission electron microscopy (TEM), scanning transmission electron microscopy (STEM), or structured illumination microscopy (SIM) systems.

1. A charged particle assessment system comprising:
a charged-particle beam apparatus configured to direct a charged particle beam onto a sample so that secondary particles and backscattered particles are generated in response to the charged particle beam;
an array of sensing elements configured to generate electrical signals in response to incident secondary particles or backscattered particles from the sample; and
a controller configured to selectively activate a first subset of the array of sensing elements, to selectively deactivate a second subset of the array of sensing elements and to combine the electrical signals of the selected subset into a detector output signal, wherein the selective activation and selective deactivation are based on a predicted distribution of secondary particles or backscattered particles.

2. The charged particle assessment system of claim 1 wherein the controller is further configured to operate in a ratio mode wherein the selected subset is selected to achieve a desired ratio of detection of secondary particles to backscattered particles across the array of sensing elements.

3. The charged particle assessment system of claim 1 wherein the controller is further configured to operate in a contrast mode wherein the selected subset is selected to achieve a desired contrast to noise ratio for the detector output signal.

4. The charged particle assessment system of claim 1 wherein the controller is further configured to operate in a sensitivity mode wherein the selected subset is selected to achieve a desired sensitivity to features, e.g. edges, on the sample.

5. The charged particle assessment system of claim 1 wherein the controller is further configured to operate in an inward radial mode wherein the selected subset consists of sensing elements within a selected radius of a detector reference point, desirably a center of an impact region of particles on the detector.

6. The charged particle assessment system of claim 1 wherein the controller is further configured to operate in an outward radial mode wherein the selected subset consists of sensing elements outside a selected radius of a detector reference point, desirably a center of an impact region of particles on the detector.

7. The charged particle assessment system of claim 1 wherein the controller is further configured to operate in an annular radial mode wherein the selected subset consists of sensing elements within a selected maximum radius of a detector reference point, desirably a center of an impact region of particles on the detector, and outside a selected minimum radius of the detector reference point.

8. The charged particle assessment system of claim 1 wherein the controller is further configured to operate in a shape mode wherein the selected subset consists of sensing elements that form a shape selected from the group consisting of: a circle, an oval, an annulus, a square, a rectangle, a diamond, a rhombus, a concave-convex shape.

9. The charged particle assessment system of claim 1 wherein the controller is further configured to operate in a disjoint mode wherein the selected subset consists of sensing elements that form a plurality of disjoint regions.

10. The charged particle assessment system of claim 1 wherein the controller is configured to deactivate sensing elements not included in the selected subset, optionally by deactivating a power supply to sensing elements not included in the selected subset.

11. The charged particle assessment system of claim 1 wherein the charged-particle beam apparatus is configured to direct a plurality of charged particle beams onto the sample; and
comprising an array of sensing elements for each of the plurality of charged particle beams.

12. A non-transitory computer-readable medium including a set of instructions that is executable by one or more processors of a controller to cause the controller to control a charged particle assessment system to perform a method of configuring a detector of a charged particle assessment system, the detector having an array of sensing elements configured to generate electrical signals in response to incident secondary particles or backscattered particles from a sample, the method comprising:
selecting a first subset of the set of sensing elements for activation based on data derived from a predicted distribution of secondary particles or backscattered particles; and
selecting a second subset of the set of sensing elements for deactivation based on the predicted distribution;
wherein the first subset has a different predicted ratio of incident secondary particles to incident backscattered particles than the second subset.

13. The non-transitory computer-readable medium according to claim 12 wherein the first subset is selected to have a higher predicted ratio of incident secondary particles to incident backscattered particles than the second subset; or to have a predicted ratio of incident secondary particles to incident backscattered particles higher than a predetermined ratio; or to capture at least a predetermined proportion of secondary particles incident from the sample.

14. The non-transitory computer-readable medium according to claim 13 wherein the first subset consists of sensing elements within a selected radius of a detector reference point, desirably a center of an impact region of particles on the detector and the second subset consists of sensing elements outside the selected radius of the detector reference point.

15. The non-transitory computer-readable medium according to claim 12 wherein the first subset is selected to have a higher sensitivity to a predetermined feature type on the sample than the second subset.

16. The non-transitory computer-readable medium according to claim 12, wherein the first subset consists of sensing elements within a selected radius of a detector reference point, desirably a center of an impact region of particles on the detector, and the second subset consists of sensing elements outside the selected radius of the detector reference point.

17. The non-transitory computer-readable medium according to claim 12, wherein the first subset is selected to have a higher sensitivity to a predetermined feature type on the sample than the second subset.

18. The non-transitory computer-readable medium according to claim 17, wherein the first subset consists of sensing elements within a selected maximum radius of a detector reference point, desirably a center of an impact region of particles on the detector, and outside a selected minimum radius of the detector reference point and the second subset consists of sensing elements outside the selected maximum radius of the detector reference point and sensing elements within a selected minimum radius of the detector reference point.

19. The non-transitory computer-readable medium according to claim 12, wherein the first subset consists of sensing elements that form a shape selected from the group consisting of: a circle, an oval, an annulus, a square, a rectangle, a diamond, a rhombus, a concave-convex shape.

20. A non-transitory computer-readable medium including a set of instructions that is executable by one or more processors of a controller to cause the controller to control a charged particle assessment system to perform a method of configuring a detector of a charged particle assessment system, the detector having an array of sensing elements configured to generate electrical signals in response to incident secondary particles or backscattered particles from a sample, the method comprising:
scanning a charged particle beam across a calibration sample having a known topography;
receiving electrical signals from the sensing elements in response to secondary particles and backscattered particles generated in response to the charged particle beam to obtain a combined distribution of secondary particles and backscattered particles as a function of position on the detector;
estimating a distribution of backscattered particles amongst the secondary particles and backscattered particles as a function of position on the detector;
subtracting the distribution of backscattered particles from the combined distribution of secondary particles and backscattered particles to obtain a distribution of secondary particles; and
selecting a subset of the sensing elements to be used for assessment of a sample based on the distribution of backscattered particles and the distribution of secondary particles.
